(19) United States
(12) Patent Application Publication
(10) Pub. No.: US 2017/0074949 A1
(43) Pub. Date: Mar. 16, 2017

(54) SENSOR, SENSOR SYSTEM, AND ELECTRIC MOTOR DEVICE

(71) Applicant: KABUSHIKI KAISHA TOSHIBA, Tokyo (JP)

(72) Inventors: Yoshihiro HIGASHI, Komatsu (JP); Yoshihiko FUJI, Kawasaki (JP); Hideaki FUKUZAWA, Kawasaki (JP); Michiko HARA, Yokohama (JP); Motomichi SHIBANO, Atsugi (JP)

(73) Assignee: KABUSHIKI KAISHA TOSHIBA

(21) Appl. No.: 15/247,957

(22) Filed: Aug. 26, 2016

(30) Foreign Application Priority Data
Sep. 10, 2015 (JP) 2015-178948
Mar. 17, 2016 (JP) 2016-054320

(51) Int. Cl. G01R 33/02; H02K 11/215; G01R 33/00

(52) U.S. Cl. CPC G01R 33/02; G01R 33/0023; H02K 11/215

(57) ABSTRACT

According to one embodiment, a sensor includes a supporter, a film portion, a first sensing element, a second sensing element, and a processor. The film portion is supported by the supporter, and is deformable. The first sensing element is fixed to the supporter, and Includes a first magnetic layer, a second magnetic layer, and a first intermediate layer provided between the first magnetic layer and the second magnetic layer. The second sensing element is fixed to the film portion, and includes a third magnetic layer, a fourth magnetic layer, and a second intermediate layer provided between the third magnetic layer and the fourth magnetic layer. The processor outputs an output signal when a first signal is in a first state. The first signal is obtained from the first sensing element. The output signal is based on a second signal obtained from the second sensing element.

### CROSS-REFERENCE TO RELATED APPLICATIONS

This application is based upon and claims the benefit of priority from Japanese Patent Application No. 2015-178948, filed on Sep. 10, 2015, and Japanese Patent Application No. 2016-054320, filed on Mar. 17, 2016; the entire contents of which are incorporated herein by reference.

### FIELD

Embodiments described herein relate generally to a sensor, a sensor system, and an electric motor device.

### BACKGROUND

For example, there is a sensor that uses a magnetic body. For example, a sound wave is sensed by the sensor. The condition of an object can be ascertained by sensing a sound wave generated by the object. It is desirable for the sensor to sense with high sensitivity.

### BRIEF DESCRIPTION OF THE DRAWINGS

FIG. 1A to FIG. 1C are schematic views illustrating a sensor according to a first embodiment;

FIG. 2 is a schematic view illustrating the sensor according to the first embodiment;

FIG. 3A to FIG. 3C are schematic views illustrating operations of the sensor according to the first embodiment;

FIG. 4 is a schematic view illustrating another sensor according to the first embodiment;

FIG. 5 is a schematic view illustrating another sensor according to the first embodiment;

FIG. 6 is a schematic view illustrating another sensor according to the first embodiment;

FIG. 7A to FIG. 7G are schematic views illustrating another sensor according to the first embodiment;

FIG. 8 is a schematic view illustrating another sensor according to the first embodiment;

FIG. 9A and FIG. 9B are circuit diagrams illustrating portions of the sensor according to the first embodiment;

FIG. 10 is a schematic view illustrating a sensor system according to a second embodiment;

FIG. 11 is a schematic view illustrating an electric motor device according to a third embodiment;

FIG. 12 is a schematic cross-sectional view illustrating a sensor according to a fourth embodiment;

FIG. 13 is a schematic plan view illustrating the sensor according to the fourth embodiment;

FIG. 14 is a schematic cross-sectional view illustrating a sensor according to a fifth embodiment;

FIG. 15 is a schematic view illustrating the sensor according to the embodiment;

FIG. 16 is a schematic view illustrating the sensor according to the embodiment;

FIG. 17 is a schematic view illustrating the sensor according to the embodiment; and

FIG. 18 is a schematic view illustrating the sensor according to the embodiment.

### DETAILED DESCRIPTION

According to one embodiment, a sensor includes a supporter, a film portion, a first sensing element, a second sensing element, and a processor. The film portion is supported by the supporter, and deforms. The first sensing element is fixed to the supporter, and includes a first magnetic layer, a second magnetic layer, and a first intermediate layer provided between the first magnetic layer and the second magnetic layer. The second sensing element is fixed to the film portion, and includes a third magnetic layer, a fourth magnetic layer, and a second intermediate layer provided between the third magnetic layer and the fourth magnetic layer. The processor outputs an output signal when a first signal is in a first state. The first signal is obtained from the first sensing element. The output signal is based on a second signal obtained from the second sensing element. An output of the processor is different from the output signal when the first signal is in a second state different from the first state.

According to one embodiment, a sensor includes a supporter, a film portion, a first sensing element, a second sensing element, and a processor. The film portion is supported by the supporter, and deforms. The first sensing element is fixed to the supporter, and includes a first magnetic layer, a second magnetic layer, and a first intermediate layer provided between the first magnetic layer and the second magnetic layer. The second sensing element is fixed to the film portion, and includes a third magnetic layer, a fourth magnetic layer, and a second intermediate layer provided between the third magnetic layer and the fourth magnetic layer. The processor performs sensing based on a second signal when a first signal is in the first state. The first signal is obtained from the first sensing element. The second signal is obtained from the second sensing element.

According to one embodiment, a sensor includes a supporter, a film portion, a first sensing element, a second sensing element, and a processor. The film portion is supported by the supporter, and deforms. The first sensing element is fixed to the supporter, and includes a first magnetic layer, a second magnetic layer, and a first intermediate layer provided between the first magnetic layer and the second magnetic layer. The second sensing element is fixed to the film portion, and includes a third magnetic layer, a fourth magnetic layer, and a second intermediate layer provided between the third magnetic layer and the fourth magnetic layer.

The processor outputs an output signal based on a second signal when a first signal is in a first state. The first signal is obtained from the first sensing element. The second signal being obtained from the second sensing element.

Various embodiments will be described hereinafter with reference to the accompanying drawings.

The drawings are schematic or conceptual. The relationship between the thickness and the width of each portion, and the size ratio between the portions are not necessarily identical to those in reality. Furthermore, the same portion may be shown with different dimensions or ratios in different figures.

In the present specification and drawings, the same elements as those described previously with reference to earlier figures are labeled with like reference numerals, and the detailed description thereof is omitted as appropriate.

### First Embodiment

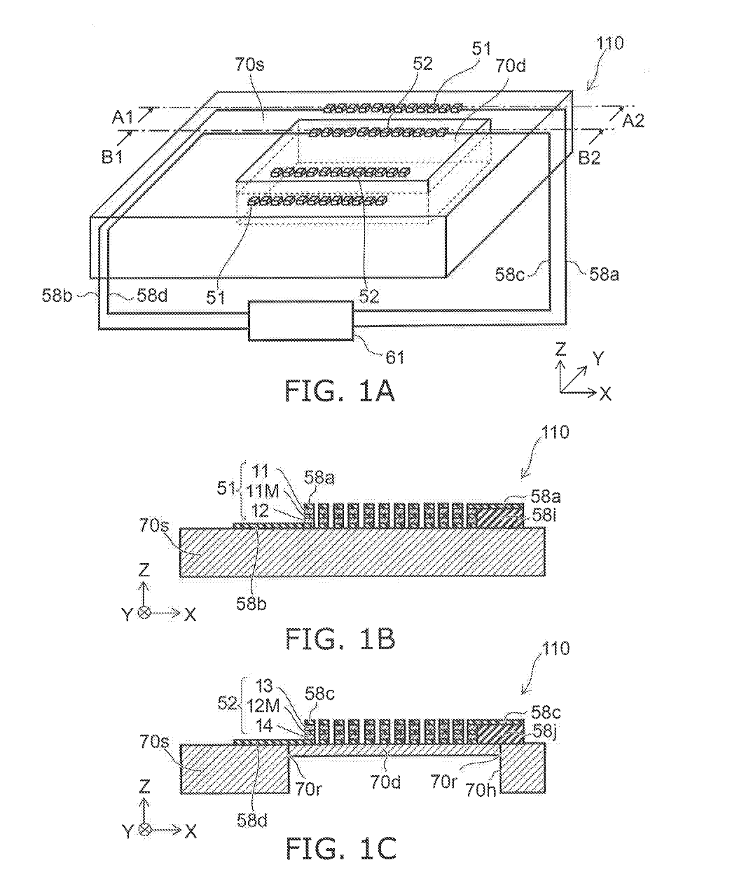

FIG. 1A to FIG. 1C are schematic views illustrating a sensor according to a first embodiment.

FIG. 1A is a perspective view. FIG. 1B is a line A1-A2 cross-sectional view of FIG. 1A. FIG. 1C is a line B1-B2 cross-sectional view of FIG. 1A.

As shown in FIG. 1A, the sensor 110 according to the embodiment includes a holder 70s (a supporter), a film portion 70d, a first sensing element 51, and a second sensing element 52.

The film portion 70d is held (supported) by the holder 70s. The film portion 70d deforms. The film portion 70d is deformable. For example, a substrate that is used to form the film portion 70d and the holder 70s is provided. The substrate is, for example, a silicon substrate. A hollow 70h is provided in the substrate by removing a portion of the substrate (referring to FIG. 1C). For example, the thin portion of the substrate is used as the film portion 70d. The thick portion of the substrate is used as the holder 70s.

The first sensing element 51 is fixed to the holder 70s. For example, the first sensing element 51 is provided on a portion of the holder 70s.

The second sensing element 52 is fixed to the film portion 70d. For example, the second sensing element 52 is provided on a portion of the film portion 70d.

A direction from the film portion 70d toward the first sensing element 51 is taken as a Z-axis direction. One direction perpendicular to the Z-axis direction is taken as an X-axis direction. A direction perpendicular to the Z-axis direction and the X-axis direction is taken as a Y-axis direction.

In the example, multiple first sensing elements 51 and multiple second sensing elements 52 are provided. In the example, the multiple first sensing elements 51 are arranged along the X-axis direction. In the example, the multiple second sensing elements 52 are arranged along the X-axis direction. For example, the second sensing element 52 is arranged with the first sensing element 51 in the Y-axis direction. For example, the multiple first sensing elements 51 are connected in series to each other. For example, the multiple second sensing elements 52 are connected in series to each other. In the embodiment, the number of the first sensing elements 51 may be one. The number of the second sensing elements 52 may be one. The number of the first sensing elements 51 is arbitrary. The number of the second sensing elements 52 is arbitrary.

As shown in FIG. 1B, the first sensing element 51 includes a first magnetic layer 11, a second magnetic layer 12, and a first intermediate layer 11M. The first intermediate layer 11M is provided between the first magnetic layer 11 and the second magnetic layer 12. The second magnetic layer 12 is separated from the first magnetic layer 11 substantially along the Z-axis direction. In the example, the second magnetic layer 12 is provided between the first magnetic layer 11 and the film portion 70d. In the embodiment, the first magnetic layer 11 may be provided between the second magnetic layer 12 and the film portion 70d.

In the example, a first electrode 58a and a second electrode 58b are provided. For example, the first magnetic layer 11, the second magnetic layer 12, and the first intermediate layer 11M are provided between the first electrode 58a and the second electrode 58b. The resistance of the first sensing element 51 is sensed by applying a voltage between the first electrode 58a and the second electrode 58b. A first insulating layer 58i is provided between the first electrode 58a and the holder 70s.

As shown in FIG. 1C, the second sensing element 52 includes a third magnetic layer 13, a fourth magnetic layer 14, and a second intermediate layer 12M. The second intermediate layer 12M is provided between the third magnetic layer 13 and the fourth magnetic layer 14. The fourth magnetic layer 14 is separated from the third magnetic layer 13 substantially along the Z-axis direction. In the example, the fourth magnetic layer 14 is provided between the third magnetic layer 13 and the film portion 70d. In the embodiment, the third magnetic layer 13 may be provided between the fourth magnetic layer 14 and the film portion 70d.

In the example, a third electrode 58c and a fourth electrode 58d are provided. For example, the third magnetic layer 13, the fourth magnetic layer 14, and the second intermediate layer 12M are provided between the third electrode 58c and the fourth electrode 58d. The resistance of the second sensing element 52 is sensed by applying a voltage between the third electrode 58c and the fourth electrode 58d. A second insulating layer 58j is provided between the third electrode 58c and the film portion 70d.

For example, the magnetization of the first magnetic layer 11 changes according to a magnetic field applied to the first sensing element 51. For example, the magnetization of the second magnetic layer 12 does not change easily compared to the magnetization of the first magnetic layer 11. The first magnetic layer 11 is, for example, a free magnetic layer. The second magnetic layer 12 is, for example, a fixed magnetic layer. The second magnetic layer 12 is, for example, a reference layer.

The angle between the magnetization of the first magnetic layer 11 and the magnetization of the second magnetic layer 12 changes according to the magnetic field applied to the first sensing element 51. The electrical resistance between the first magnetic layer 11 and the second magnetic layer 12 changes according to the change of the angle. For example, the change is based on a magnetoresistance effect.

In the embodiment, the magnetization of the second magnetic layer 12 may change. In such a case as well, the angle between the magnetization of the first magnetic layer 11 and the magnetization of the second magnetic layer 12 changes according to the magnetic field applied to the first sensing element 51.

On the other hand, in the second sensing element 52, the magnetization of the third magnetic layer 13 changes. For example, the magnetization of the fourth magnetic layer 14 does not change easily compared to the magnetization of the third magnetic layer 13. The third magnetic layer 13 is, for example, a free magnetic layer. The fourth magnetic layer 14 is, for example, a fixed magnetic layer. The fourth magnetic layer 14 is, for example, a reference layer.

The second sensing element 52 is fixed to the film portion 70d that deforms. For example, pressure such as a sound wave (including an ultrasonic wave) or the like is applied to the film portion 70d. The film portion 70d deforms due to the pressure. Thereby, strain is generated in the magnetic layer of the second sensing element 52. The strain is, for example, anisotropic strain. The magnetization of the third magnetic layer 13 changes due to the strain. For example, the change is based on an inverse magnetostrictive effect. Thus, the magnetization of the third magnetic layer 13 changes according to the deformation of the film portion 70d. Thereby, the angle between the magnetization of the third magnetic layer 13 and the magnetization of the fourth magnetic layer 14 changes. In other words, the angle between the magnetization of the third magnetic layer 13 and the magnetization of the fourth magnetic layer 14 changes according to the deformation of the film portion 70d. Thereby, the electrical resistance between the third magnetic layer 13 and the fourth magnetic layer 14 changes. For example, the change of the resistance is based on a magnetoresistance effect.

In the embodiment, the magnetization of the fourth magnetic layer 14 may change. In such a case as well, the angle between the magnetization of the third magnetic layer 13 and the magnetization of the fourth magnetic layer 14 changes according to the strain generated in the second sensing element 52.

The second sensing element 52 is provided proximally to the first sensing element 51. When a magnetic field from the outside is applied to the first sensing element 51, substantially the same magnetic field is applied to the second sensing element 52 as well.

Therefore, in the second sensing element 52, the magnetization of the third magnetic layer 13 is affected by both the deformation of the film portion 70d and the magnetization applied from the outside.

For example, the object to be sensed by the sensor 110 is an electric motor. For example, in the electric motor, an axis rotates due to the rotation of a magnet (including an electromagnet). The rotation of the axis is utilized. A sound wave (including an ultrasonic wave) is generated by the axis. For example, the sound wave is generated by contact between the axis and another member, etc. The sound wave when the electric motor is abnormal is different from the sound wave when the electric motor is normal. There are cases where the sound wave changes as the electric motor approaches failure. The failure of the object to be sensed (the electric motor, etc.) can be predicted by sensing such a sound wave.

In such an application, a magnetic field is generated simultaneously with the sound wave from the object to be sensed. The magnetic field changes periodically. Other than the sound wave to be sensed, a strong magnetic field is applied to the sensor in the case where the sensor is provided proximally to the object to be sensed and high-precision sensing is performed. Because sensors that use magnetic layers have high sensitivity, the effect of the magnetic field is large. Such a magnetic field becomes noise.

In such an application, the effect of the noise can be reduced by using two sensing elements. A processor 61 processes the signals obtained from such sensing elements.

For example, the processor 61 outputs an output signal based on a second signal obtained from the second sensing element 52 when a first signal obtained from the first sensing element 51 is in a prescribed state (a first state). The first state is, for example, the state in which the magnetic field applied from the outside is small. The processor 61 does not output the output signal when the first signal is in a second state. The second state is a state that is different from the first state and is, for example, when the magnetic field applied from the outside is large. By such processing, highly-sensitive sensing is possible in which the effect of the magnetic field is suppressed. According to the embodiment, a sensor in which the sensitivity can be increased can be provided.

An example of the processor 61 will now be described.

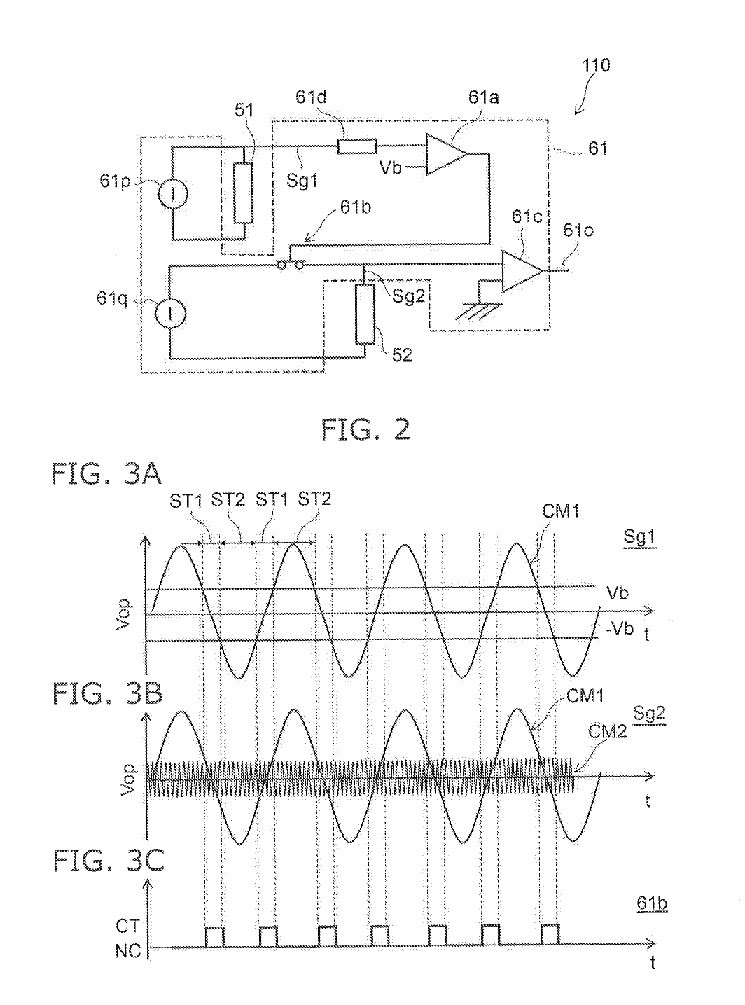

FIG. 2 is a schematic view illustrating the sensor according to the first embodiment.

As shown in FIG. 2, for example, the processor 61 includes a comparison circuit 61a and a switch circuit 61b. The comparison circuit 61a compares a first signal Sg1 of the first sensing element 51 to a reference value Vb. Based on the output of the comparison, the switch circuit 61b allows or Interrupts the current supplied to the second sensing element 52. In other words, the switch circuit 61b switches between a conducting state and a nonconducting state.

In the example, a full-wave rectifying circuit 61d and an output unit 61c are provided. In the example, one end of the second sensing element 52 is connected to the input of the output unit 61c.

For example, a current is supplied from a first current source 61p to the first sensing element 51. The first signal Sg1 that is obtained from the first sensing element 51 is input to the full-wave rectifying circuit 61d. The output of the full-wave rectifying circuit 61d is input to the comparison circuit 61a. The voltage of the reference value Vb is input to the comparison circuit 61a. The comparison circuit 61a compares the reference value Vb to the absolute value (e.g., the effective value) of the first signal Sg1. The result of the comparison is output from the comparison circuit 61a.

For example, the first state is the state in which the absolute value (e.g., the effective value) of the first signal Sg1 is smaller than the reference value Vb. The second state is the state in which the absolute value (e.g., the effective value) of the first signal Sg1 is not less than the reference value Vb. In other words, the amplitude of the first signal Sg1 in the first state is smaller than the threshold (corresponding to the reference value Vb). The amplitude of the first signal Sg1 in the second state is the threshold or more.

The signal of the result of the comparison is supplied to the switch circuit 61b. When in the first state, for example, the switch circuit 61b is in the conducting state. When in the second state, the switch circuit 61b is in the nonconducting state (the disconnected state).

In the first state, a current is supplied from a second current source 61q to the second sensing element 52. The signal (a second signal Sg2) that is sensed by the second sensing element 52 is obtained from the second sensing element 52. Thereby, in the first state, the second signal Sg2 of the second sensing element 52 is output as an output signal 61o via the output unit 61c. On the other hand, in the second state, a current is not supplied to the second sensing element 52. The second signal Sg2 is not generated. In other words, in the second state, the second signal Sg2 is not output.

An example of the signals of these sensing elements will now be described.

FIG. 3A to FIG. 3C are schematic views illustrating operations of the sensor according to the first embodiment.

In these figures, the horizontal axis is a time t. FIG. 3A corresponds to the first signal Sg1 of the first sensing element 51. The vertical axis of FIG. 3A is a voltage Vop. FIG. 3B corresponds to the second signal Sg2 of the second sensing element 52. In the figures, the two components of the second signal Sg2 are shown separately for easier understanding. The vertical axis of FIG. 3B is the voltage Vop. FIG. 3C illustrates the state of the switch circuit 61b. In FIG. 3C, a current flows in the switch circuit 61b in a conducting state CT. The signal is transmitted. In FIG. 3C, a current does not flow in the switch circuit 61b in a nonconducting state NC. The signal is not transmitted.

As shown in FIG. 3A, the first signal Sg1 includes a component CM1 of a first frequency. The first frequency is low. For example, the component CM1 of the first frequency corresponds to the change of the magnetic field applied from the electric motor.

As shown in FIG. 3B, the second signal Sg2 includes a component CM2 of a second frequency. The second frequency is higher than the first frequency. The component CM2 of the second frequency is, for example, the sound wave of the object to be sensed. In addition to the component CM2 of the second frequency, the second signal Sg2 further includes the component CM1 of the first frequency (the component of the magnetic field). The second signal Sg2 includes the composite signal of the component CM1 of the first frequency and the component CM2 of the second frequency.

For example, the first frequency is not less than 100 Hz and not more than 800 Hz. For example, the second frequency is not less than 20 kHz and not more than 200 KHz. For example, the second frequency is not less than 20 times and not more than 2000 times the first frequency. For example, the second frequency may be not less than 20 kHz and not more than 80 KHz. For example, the second frequency may be not less than 20 times and not more than 800 times the first frequency.

The first signal Sg1 corresponds to the change of a first resistance between the first magnetic layer 11 and the second magnetic layer 12. The second signal Sg2 corresponds to the change of a second resistance between the third magnetic layer 13 and the fourth magnetic layer 14. The first signal Sg1 corresponds to the change of the angle between the magnetization of the first magnetic layer 11 and the magnetization of the second magnetic layer 12. The second signal Sg2 corresponds to the change of the angle between the magnetization of the third magnetic layer 13 and the magnetization of the fourth magnetic layer 14.

Thus, the first signal Sg1 includes a first component (the component CM1 of the first frequency) corresponding to the change of the magnetic field received by the first sensing element 51. The second signal Sg2 includes a second component (the component CM2 of the second frequency) corresponding to the deformation of the film portion 70d. The second signal Sg2 also includes the first component.

Thus, the second signal Sg2 that includes the first component and the second component is extracted based on the state (a first state ST1 or a second state ST2) of the first signal Sg1 including the first component.

As shown in FIG. 3A, the amplitude of the first signal Sg1 in the first state ST1 is less than the amplitude of the first signal Sg1 in the second state ST2. For example, the reference value Vb (the threshold) is used to set such a first state ST1 and such a second state ST2.

As shown in FIG. 3A, the state in which the amplitude of the component CM1 of the first frequency is smaller than the reference value (+Vb and −Vb) corresponds to the first state ST1. The state in which the amplitude of the component CM1 of the first frequency is the reference value (+Vb and −Vb) or more corresponds to the second state ST2.

As shown in FIG. 3C, the switch circuit 61b is switched to the conducting state CT in the first state ST1. The switch circuit 61b is switched to the nonconducting state NC in the second state ST2.

Thus, for example, based on the output of the comparison, the switch circuit 61b allows or interrupts the current supplied to the second sensing element 52. Thereby, the processor 61 outputs the output signal 61o based on the second signal Sg2 obtained from the second sensing element 52 when the first signal Sg1 obtained from the first sensing element 51 is in the first state ST1. The processor 61 does not output the output signal 61o when the first signal Sg1 is in the second state ST2 that is different from the first state ST1.

In the sensor 110, the second signal Sg2 that corresponds to the sound wave of the object to be sensed is extracted when the first signal Sg1 corresponding to the magnetic field that becomes noise is small. Thereby, the effect of the magnetic field can be suppressed. Thereby, highly-sensitive sensing is possible.

On the other hand, there is a method of a reference example in which the difference between the output of the first sensing element 51 and the output of the second sensing element 52 is obtained. In such a case, for example, the effect of the magnetic field that becomes noise is canceled; and only the signal that corresponds to the sound wave of the object to be sensed can be extracted. However, the resistance change of the sensing element reaches a saturated state if the magnetic field is strong when sensing the sound from an electric motor, etc. Although the direction of the magnetization of the free magnetic layer of the sensing element changes according to the magnetic field, the change of the direction of the magnetization saturates and the direction of the magnetization no longer changes when the magnetic field has a constant strength or more. In such a state, the change of the magnetization does not occur even when strain is generated in the magnetic layer by the deformation of the film portion 70d based on the sound wave. Therefore, in the reference example that senses the difference of the two sensing elements, it is difficult to sufficiently increase the sensitivity of the sensing when there is a strong magnetic field.

Conversely, in the embodiment, the second signal Sg2 is extracted when the first signal Sg1 of the first sensing element 51 based on the effect of the magnetic field is small. Thereby, the effect of the strong magnetic field can be suppressed. The state in which the change of the direction of the magnetization saturates due to the strong magnetic field can be eliminated. Thereby, highly-sensitive sensing is possible. According to the embodiment, a sensor in which the sensitivity can be increased can be provided.

In the embodiment, the second signal Sg2 that is extracted in the first state ST1 is the composite signal of the component CM1 (the first component) of the first frequency based on the change of the magnetic field and the component CM2 (the second component) of the second frequency based on the sound wave. In other words, the first component is added to the second component to be sensed in the second signal Sg2. Because the frequency of the first component is sufficiently lower than the frequency of the second component, the effect of the first component on the sensing is small. Even when the first component exists, high sensing sensitivity can be maintained.

FIG. 4 is a schematic view illustrating another sensor according to the first embodiment.

In the sensor 111 according to the embodiment, as shown in FIG. 4, the processor 61 includes the comparison circuit 61a, the switch circuit 61b, and the output unit 61c. The comparison circuit 61a compares the reference value Vb to the first signal Sg1 of the first sensing element 51. The switch circuit 61b opens and closes the path between the second sensing element 52 and the output unit 61c based on the output of the comparison. Otherwise, the sensor 111 is similar to the sensor 110; and a description is therefore omitted.

In such a case as well, the processor 61 outputs the output signal 61o based on the second signal Sg2 obtained from the second sensing element 52 when the first signal Sg1 obtained from the first sensing element 51 is in the first state ST1. The processor 61 does not output the output signal 610 when the first signal Sg1 is in the second state ST2 that is different from the first state ST1. Thereby, for example, the effect of the magnetic field can be suppressed. Thereby, highly-sensitive sensing is possible.

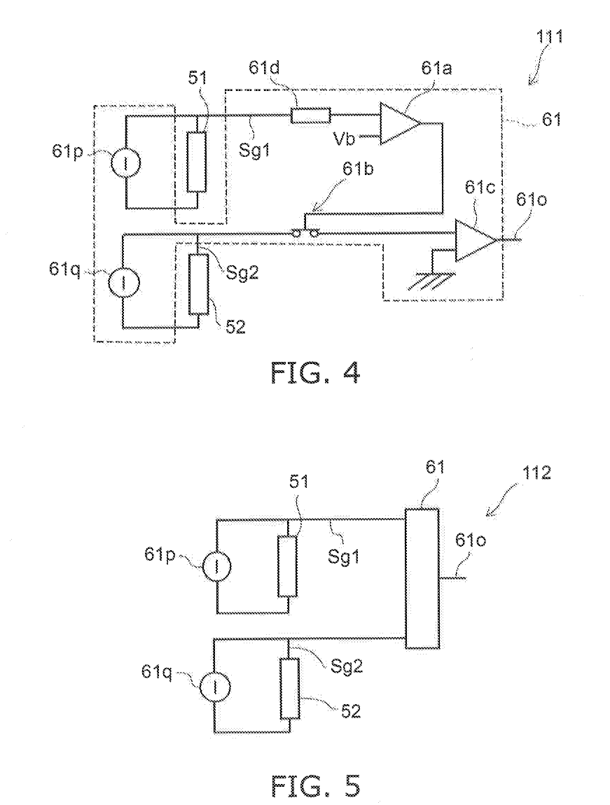

FIG. 5 is a schematic view illustrating another sensor according to the first embodiment.

In the sensor 112 according to the embodiment as shown in FIG. 5, the first signal Sg1 obtained from the first sensing element 51 and the second signal Sg2 obtained from the second sensing element 52 are input to the processor 61. Otherwise, the sensor 112 is similar to the sensor 110; and a description is therefore omitted.

The processor 61 performs the sensing based on the second signal Sg2 obtained from the second sensing element 52 when the first signal Sg1 obtained from the first sensing element 51 is in the first state ST1. The processor 61 does not perform the sensing when the first signal Sg1 is in the second state ST2 that is different from the first state ST1. The result of the sensing is output as the output signal 610 (the information).

For example, A/D conversion of the first signal Sg1 and the second signal Sg2 is performed. The converted digital signal is processed by the processor 61. The time domain in which the amplitude of the first signal Sg1 is small is recognized from the digital signal corresponding to the first signal Sg1. The second signal Sg2 (the digital signal) that corresponds to the time domain is extracted. The extracted signal is output as the output signal 610 (the information).

Thereby, for example, the effect of the magnetic field can be suppressed. In the sensor 112 as well, highly-sensitive sensing is possible.

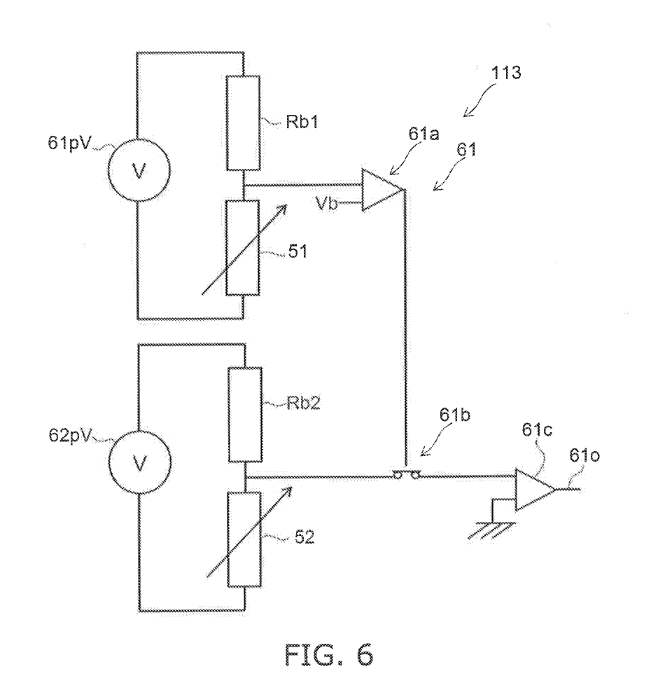

FIG. 6 is a schematic view illustrating another sensor according to the first embodiment.

As shown in FIG. 6, in the sensor 113 as well, the processor 61 includes the comparison circuit 61a and the switch circuit 61b. In the example, a first constant voltage source 61pV and a second constant voltage source 62pV are provided.

For example, the first sensing element 51 is connected in series to a first fixed resistor Rb1. The first constant voltage source 61pV applies a voltage to the first sensing element 51 and the first fixed resistor Rb1. The second sensing element 52 is connected in series to a second fixed resistor Rb2. The second constant voltage source 62pV applies a voltage to the second sensing element 52 and the second fixed resistor Rb2.

The connection point between the first sensing element 51 and the first fixed resistor Rb1 is connected to the input of the comparison circuit 61a. The connection point between the second sensing element 52 and the second fixed resistor Rb2 is connected to the input of the switch circuit 61b.

The comparison circuit 61a compares the reference value Vb to the first signal Sg1 of the connection point between the first sensing element 51 and the first fixed resistor Rb1. The switch circuit 61b switches between the conducting state and the nonconducting state based on the output of the comparison. When the switch circuit 61b is in the conducting state, the signal of the connection point between the second sensing element 52 and the second fixed resistor Rb2 is connected to the input of the output unit 61c. When the switch circuit 61b is in the nonconducting state, the signal of the connection point between the second sensing element 52 and the second fixed resistor Rb2 is not connected to the input of the output unit 61c.

For example, a half bridge configuration of a Wheatstone bridge is used in the example. For example, the full-wave rectifying circuit 61d is provided between the input of the comparison circuit 61a and the connection point between the first sensing element 51 and the first fixed resistor Rb1.

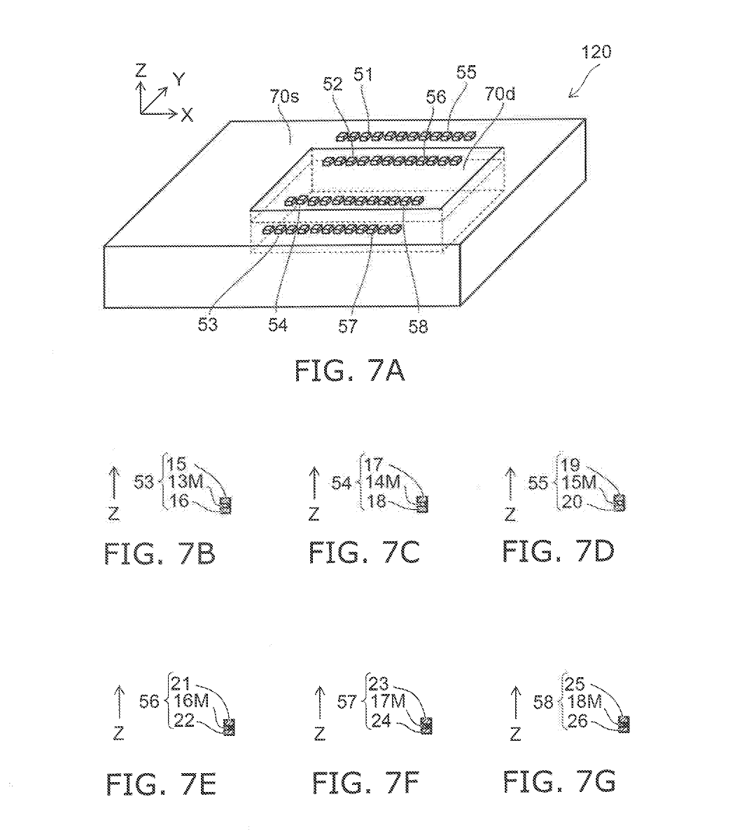

FIG. 7A to FIG. 7G are schematic views illustrating another sensor according to the first embodiment.

FIG. 7A is a perspective view. FIG. 7B to FIG. 7G are cross-sectional views.

As shown in FIG. 7A, the sensor 120 includes third to eighth sensing elements 53 to 58 in addition to the holder 70s, the film portion 70d, the first sensing element 51, and the second sensing element 52. The holder 70s, the film portion 70d, the first sensing element 51, and the second sensing element 52 are similar to those of the sensor 110; and a description is therefore omitted. Examples of the third to eighth sensing elements 53 to 58 will now be described.

The third sensing element 53 is fixed to the holder 70s. In the example, the film portion 70d is provided between the position in the Y-axis direction at which the third sensing element 53 is provided and the position in the Y-axis direction at which the first sensing element 51 is provided. As shown in FIG. 7B, the third sensing element 53 includes a fifth magnetic layer 15, a sixth magnetic layer 16, and a third intermediate layer 13M that is provided between the fifth magnetic layer 15 and the sixth magnetic layer 16. For example, the material that is included in the first magnetic layer 11 is included in the fifth magnetic layer 15. For example, the material that is included in the second magnetic layer 12 is included in the sixth magnetic layer 16. The direction of the magnetization of the sixth magnetic layer 16 (e.g., the reference layer) is the reverse of the direction of the magnetization of the second magnetic layer 12. The material that is included in the first intermediate layer 11M is included in the third intermediate layer 13M.

The fourth sensing element 54 is fixed to the film portion 70d. In the example, the position in the Y-axis direction at which the fourth sensing element 54 is provided is between the position in the Y-axis direction at which the third sensing element 53 is provided and the position in the Y-axis direction at which the second sensing element 52 is provided. As shown in FIG. 7C, the fourth sensing element 54 includes a seventh magnetic layer 17, an eighth magnetic layer 18, and a fourth intermediate layer 14M that is provided between the seventh magnetic layer 17 and the eighth magnetic layer 17. For example, the material of the seventh magnetic layer 17 is different from the material of the third magnetic layer 13. The polarity of the magnetostriction constant of the seventh magnetic layer 17 is the reverse of the polarity of the magnetostriction constant of the third magnetic layer 13. The magnetostriction constant of the third magnetic layer 13 is one of positive or negative. The magnetostriction constant of the seventh magnetic layer 17 is the other of positive or negative. For example, the material that is included in the fourth magnetic layer 14 is included in the eighth magnetic layer 18. The material that is included in the second intermediate layer 12M is included in the fourth intermediate layer 14M.

A fifth sensing element 55 is fixed to the holder 70s. In the example, the fifth sensing element 55 is arranged with the first sensing element 51 in the X-axis direction. As shown in FIG. 7D, the fifth sensing element 55 includes a ninth magnetic layer 19, a tenth magnetic layer 20, and a fifth intermediate layer 15M that is provided between the ninth magnetic layer 19 and the tenth magnetic layer 20. For example, the material that is included in the first magnetic layer 11 is included in the ninth magnetic layer 19. For example, the material that is included in the second magnetic layer 12 is included in the tenth magnetic layer 20. The direction of the magnetization of the tenth magnetic layer 20 (e.g., the reference layer) is the same as the direction of the magnetization of the second magnetic layer 12. The material that is included in the first intermediate layer 11M is included in the fifth intermediate layer 15M.

A sixth sensing element 56 is fixed to the film portion 70d. In the example, the sixth sensing element 56 is arranged with the second sensing element 52 in the X-axis direction. As shown in FIG. 7E, the sixth sensing element 56 includes an eleventh magnetic layer 21, a twelfth magnetic layer 22, and a sixth intermediate layer 16M that is provided between the eleventh magnetic layer 21 and the twelfth magnetic layer 22. For example, the material of the eleventh magnetic layer 21 is the same as the material of the third magnetic layer 13. For example, the material that is included in the fourth magnetic layer 14 is included in the twelfth magnetic layer 22. The material that is included in the second intermediate layer 12M is included in the sixth intermediate layer 16M.

A seventh sensing element 57 is fixed to the holder 70s. In the example, the seventh sensing element 57 is arranged with the third sensing element 53 in the X-axis direction. As shown in FIG. 7F, the seventh sensing element 57 includes a thirteenth magnetic layer 23, a fourteenth magnetic layer 24, and a seventh intermediate layer 17M that is provided between the thirteenth magnetic layer 23 and the fourteenth magnetic layer 24. For example, the material that is included in the fifth magnetic layer 15 is included in the thirteenth magnetic layer 23. For example, the material that is included in the sixth magnetic layer 16 is included in the fourteenth magnetic layer 24. The direction of the magnetization of the fourteenth magnetic layer 24 (e.g., the reference layer) is the reverse of the direction of the magnetization of the second magnetic layer 12. The material that is included in the third intermediate layer 13M is included in the seventh intermediate layer 17M.

The eighth sensing element 58 is fixed to the film portion 70d. In the example, the eighth sensing element 53 is arranged with the fourth sensing element 54 in the X-axis direction. As shown in FIG. 7G, the eighth sensing element 58 includes a fifteenth magnetic layer 25, a sixteenth magnetic layer 26, and an eighth intermediate layer 18M that is provided between the fifteenth magnetic layer 25 and the sixteenth magnetic layer 26. For example, the material of the fifteenth magnetic layer 25 is different from the material of the third magnetic layer 13. The polarity of the magnetostriction constant of the fifteenth magnetic layer 25 is the reverse of the polarity of the magnetostriction constant of the third magnetic layer 13. The magnetostriction constant of the third magnetic layer 13 is one of positive or negative. The magnetostriction constant of the fifteenth magnetic layer 25 is the other of positive or negative. For example, the material that is included in the fourth magnetic layer 14 is included in the sixteenth magnetic layer 26. The material that is included in the fourth intermediate layer 14M is included in the eighth intermediate layer 18M.

The first magnetic layer 11, the third magnetic layer 13, the fifth magnetic layer 15, the seventh magnetic layer 17, the ninth magnetic layer 19, the eleventh magnetic layer 21, the thirteenth magnetic layer 23, and the fifteenth magnetic layer 25 are, for example, free magnetic layers.

The second magnetic layer 12, the fourth magnetic layer 14, the sixth magnetic layer 16, the eighth magnetic layer 18, the tenth magnetic layer 20, the twelfth magnetic layer 22, the fourteenth magnetic layer 24, and the sixteenth magnetic layer 26 are, for example, fixed magnetic layers (e.g., reference layers).

For example, a fixed magnetic layer may be provided between the free magnetic layer and the holder 70s. For example, a free magnetic layer may be provided between the fixed magnetic layer and the holder 70s. For example, a fixed magnetic layer may be provided between the free magnetic layer and the film portion 70d. For example, a free magnetic layer may be provided between the fixed magnetic layer and the film portion 70d.

In the example as recited above, a sensing element (the fifth sensing element 55) that has a magnetization vector having the same orientation as the magnetization vector of the reference layer (the second magnetic layer 12) of the first sensing element 51 is provided on the holder 70s. Sensing elements (the third sensing element 53 and the seventh sensing element 57) that have magnetization vectors of the reverse orientation of the magnetization vector of the reference layer (the second magnetic layer 12) of the first sensing element 51 are further provided on the holder 70s.

Changes of the electrical resistance that have the reverse polarity occur for the changes of the magnetic fields of two sensing elements including magnetic layers (reference layers) in which the directions of the magnetizations are mutually-reverse orientations. The polarity of the change of the electrical resistance for the magnetic field in the third sensing element 53 and the seventh sensing element 57 is different from the polarity of the change of the electrical resistance for the magnetic field in the first sensing element 51 and the fifth sensing element 55.

A sensing element (the sixth sensing element 56) that has a magnetostriction constant of the same polarity as the polarity of the magnetostriction constant of the free magnetic layer (the third magnetic layer 13) of the second sensing element 52 is further provided on the film portion 70d. Sensing elements (the fourth sensing element 54 and the eighth sensing element 58) that have magnetostriction constants of polarities different from the polarity of the magnetostriction constant of the free magnetic layer (the third magnetic layer 13) of the second sensing element 52 are further provided on the film portion 70d.

For example, in a material having a positive magnetostriction constant, the magnetization changes to be aligned with the direction in which the tensile strain is applied. In a material that has a negative magnetostriction constant, the magnetization changes to be aligned with the direction in which the compressive strain is applied. Changes of the electrical resistance having reverse polarities occur when the same strain is applied to two sensing elements having magnetic layers (free magnetic layers) having mutually-different magnetostriction constants. The polarity of the change of the electrical resistance for the strain in the fourth sensing element 54 and the eighth sensing element 58 is different from the polarity of the change of the electrical resistance for the strain in the second sensing element 52 and the sixth sensing element 56.

For example, a bridge circuit can be formed from such sensing elements.

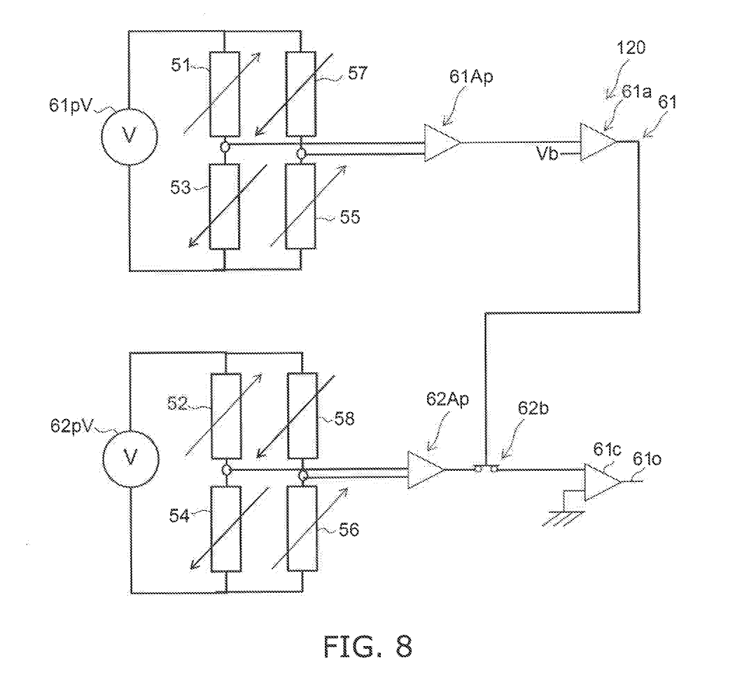

FIG. 8 is a schematic view illustrating another sensor according to the first embodiment.

As shown in FIG. 8, in the sensor 120 as well, the processor 61 includes the comparison circuit 61a and the switch circuit 61b. In the example, the first constant voltage source 61pV, the second constant voltage source 62pV, a first differential circuit 61Ap, and a second differential circuit 62Ap are provided.

For example, the first sensing element 51 and the third sensing element 53 are connected in series. The fifth sensing element 55 and the seventh sensing element 57 are connected in series. The first constant voltage source 61pV applies a voltage to the first sensing element 51 and the third sensing element 53. The first constant voltage source 61pV applies the voltage to the fifth sensing element 55 and the seventh sensing element 57. The connection point between the first sensing element 51 and the third sensing element 53 is input to a first input of the first differential circuit 61Ap. The connection point between the fifth sensing element 55 and the seventh sensing element 57 is input to a second input of the first differential circuit 61Ap. The output of the first differential circuit 61Ap is connected to the input of the comparison circuit 61a.

For example, the second sensing element 52 and the fourth sensing element 54 are connected in series. The sixth sensing element 56 and the eighth sensing element 58 are connected in series. The second constant voltage source 62pV applies a voltage to the second sensing element 52 and the fourth sensing element 54. The second constant voltage source 62pV applies the voltage to the sixth sensing element 56 and the eighth sensing element 58. The connection point between the second sensing element 52 and the fourth sensing element 54 is input to a first input of the second differential circuit 62Ap. The connection point between the sixth sensing element 55 and the eighth sensing element 58 is input to a second input of the second differential circuit 62Ap. The output of the second differential circuit 62Ap is connected to the input of the switch circuit 61b.

For example, a full bridge configuration of a Wheatstone bridge is used in the example. For example, the full-wave rectifying circuit 61d is provided between the first differential circuit 61Ap and the input of the comparison circuit 61a.

By such a circuit, a sensor in which the sensitivity can be increased can be provided.

Examples of the full-wave rectifying circuit 61d will now be described.

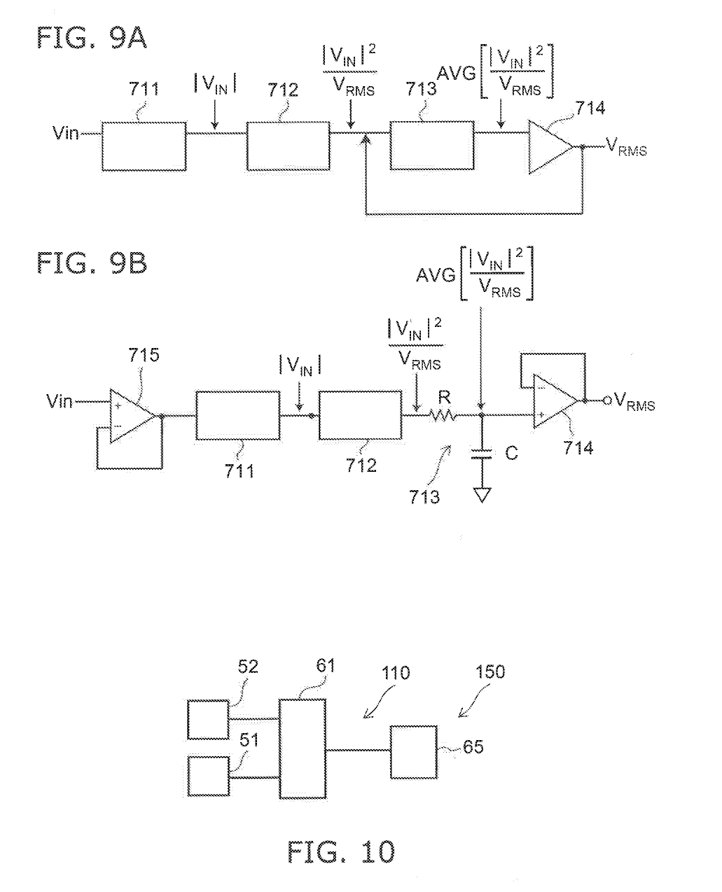

FIG. 9A and FIG. 9B are circuit diagrams illustrating portions of the sensor according to the first embodiment.

As shown in FIG. 9A, for example, the full-wave rectifying circuit 61d includes an absolute value conversion circuit 711, a square-division circuit 712, an Integration circuit 713, and a voltage follower circuit 714. An input voltage Vin (the Input signal) is input to the absolute value conversion circuit 711. The absolute value conversion circuit 711 converts the input voltage Vin into an absolute value |Vin|. The output of the absolute value conversion circuit 711 is input to the square-division circuit 712. The square-division circuit 712 outputs the value of the square of the absolute value |Vin| divided by the effective value. The output of the square-division circuit 712 is input to the integration circuit 713. The integration circuit 713 outputs the integral of the output of the square-division circuit 712 integrated over a prescribed interval. The output of the integration circuit 713 is input to the voltage follower circuit 714. The output of the voltage follower circuit 714 is fed back to the integration circuit 713. The output of the voltage follower circuit 714 is used as an output voltage V_{RMS} (the output signal) of the full-wave rectifying circuit 61d.

As shown in FIG. 9B, for example, the full-wave rectifying circuit 61d includes a voltage follower circuit 715, the absolute value conversion circuit 711, the square-division circuit 712, the integration circuit 713, and the voltage follower circuit 714. The Input voltage Vin is input to the voltage follower circuit 715. The output of the voltage follower circuit 715 is input to the absolute value conversion circuit 711. The output of the absolute value conversion circuit 711 is input to the square-division circuit 712. The output of the square-division circuit 712 is input to the Integration circuit 713. In the example, the integration circuit includes a resistor and a capacitor. The output of the integration circuit 713 is input to the voltage follower circuit 714. The output of the voltage follower circuit 714 is used as the output voltage V_{RMS} of the full-wave rectifying circuit 61d.

For example, the circuits illustrated in FIG. 9A and FIG. 9B are RMS/DC converters. In the RMS/DC converters, a direct current voltage (DC) that corresponds to the effective value of the input signal is output. In the case where the input signal is an alternating current signal, the alternating current signal is converted into a direct current signal having the effective value of the alternating current signal.

For example, the object to be sensed by the sensor 110 includes a bearing. For example, the bearing is connected to inner and outer rings with bearing components and a lubricant interposed. For example, the raceway surfaces of the inner and outer rings are damaged in the case where an abnormal load is applied due to an error when mounting the bearing, etc. Collisions occur between the damaged raceway surfaces and the bearing components. Thereby, an abnormal sound wave may be generated. By sensing the failure sound of the bearing, the failure can be predicted. The electric motor is provided at the periphery of the bearing. Therefore, the effect of the magnetic field is large in such an application as well. The embodiment is applicable to such an application.

### Second Embodiment

FIG. 10 is a schematic view illustrating a sensor system according to a second embodiment.

As shown in FIG. 10, the sensor system 150 according to the embodiment includes a communicator 65 and any of the sensors according to the embodiment recited above. The sensor 110 is used in the example.

For example, the communicator 65 transmits the output of the sensor 110. The transmission (the communication) is performed by any wired or wireless method. Wireless methods include a method that uses at least one of a radio wave or light (including infrared). According to the sensor system 150, for example, a signal that is used to predict the failure of the object to be sensed (e.g., the electric motor, etc.) can be acquired conveniently. Highly-sensitive sensing is possible. According to the embodiment, a sensor system in which the sensitivity can be increased can be provided.

### Third Embodiment

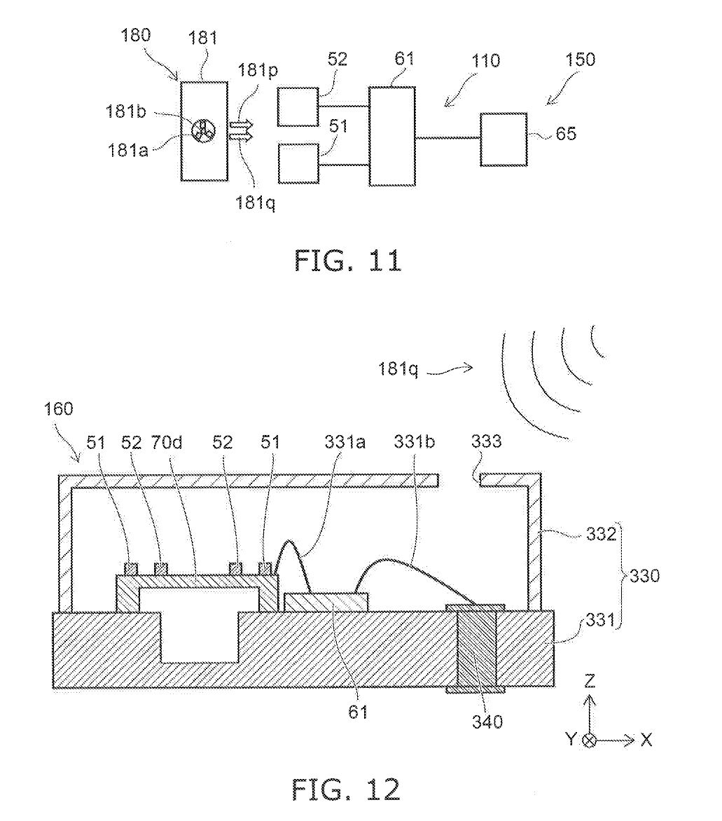

FIG. 11 is a schematic view illustrating an electric motor device according to a third embodiment.

As shown in FIG. 11, the electric motor device 180 according to the embodiment includes an electric motor 181 and any of the sensors according to the embodiment recited above. The electric motor 181 includes a magnet 181a and a member 181b. The member 181b performs one motion of a displacement or a rotation based on the displacement of the magnet 181a. The magnet 181a may include an electromagnet. For example, the member 181b is displaced based on the displacement of the magnet 181a. For example, the member 181b vibrates. For example, the member 181b rotates based on the displacement of the magnet 181a. The member 181b may be an axis that rotates.

A sound wave 181q and a magnetic field 181p from the electric motor 181 are generated. The magnetic field 181p and the sound wave 181q are applied to the sensor 110. In the first sensing element 51, the first signal Sg1 that corresponds to the magnetic field 181p is obtained. In the second sensing element 52, the second signal Sg2 that corresponds to the magnetic field 181p and the sound wave 181q is obtained. These signals are processed by the processor 61.

According to the electric motor device 180, the sound wave is sensed with high sensitivity; and, for example, the prediction of the failure can be implemented with high sensitivity.

An example of the sensing element will now be described.

The free magnetic layer (the first magnetic layer 11 and the third magnetic layer 13) include a ferromagnet material.

The free magnetic layer includes, for example, a ferromagnet material including Fe, Co, and Ni. The free magnetic layer includes, for example, at least one of an FeCo alloy or a NiFe alloy. The free magnetic layer may include a Co—Fe—B alloy, an Fe—Co—Si—B alloy, an Fe—Ga alloy having a large λs (magnetostriction constant), an Fe—Co—Ga alloy, a Tb-M-Fe alloy, a Tb-M1-Fe-M2 alloy, an Fe-M3-M4-B alloy, Ni, Fe—Al, ferrite, etc. For example, the λs (the magnetostriction constant) is large for these materials. In the Tb-M-Fe alloy recited above, M is at least one selected from the group consisting of Sm, Eu, Gd, Dy, Ho, and Er. In the Tb-M1-Fe-M2 alloy recited above, M1 is at least one selected from the group consisting of Sm, Eu, Gd, Dy, Ho, and Er. M2 is at least one selected from the group consisting of Ti, Cr, Mn, Co, Cu, Nb, Mo, W, and Ta. In the Fe-M3-M4-B alloy recited above, M3 is at least one selected from the group consisting of Ti, Cr, Mn, Co, Cu, Nb, Mo, W, and Ta. M4 is at least one selected from the group consisting of Ce, Pr, Nd, Sm, Tb, Dy, and Er. The ferrite recited above includes Fe₃O₄, (FeCo)₃O₄, etc. The thickness of the free magnetic layer is, for example, 2 nm or more.

The free magnetic layer may include boron. The free magnetic layer may include, for example, an alloy including boron (B) and at least one element selected from the group consisting of Fe, Co, and Ni. The free magnetic layer includes, for example, a Co—Fe—B alloy or an Fe—B alloy. The free magnetic layer includes, for example, a Co₄₀Fe₄₀B₂₀ alloy. The free magnetic layer may further include Ga, Al, Si, W, etc., in the case where the free magnetic layer includes an alloy including boron (B) and the at least one element selected from the group consisting of Fe, Co, and Ni. The boron concentration of the free magnetic layer is, for example, not less than 5 at. % and not more than 35 at. %; and it is favorable to be not less than 10 at. % and not more than 30 at. %.

The free magnetic layer may include Fe_{1-y}B_{y} (0<y≦0.3) or (Fe_{z}X_{1-z})_{1-y}B_{y} (X being Co or Ni, 0.8≦z<1, and 0<y≦0.3). The free magnetic layer includes, for example, Fe₈₀B₂₀ (4 nm). The free magnetic layer may include Co₄₀Fe₄₀B₂₀ (0.5 nm)/Fe₈₀B₂₀ (4 nm).

The fixed magnetic layers (e.g., the second magnetic layer 12 and the fourth magnetic layer 14) include, for example, a Co—Fe—B alloy. The fixed magnetic layer includes, for example, a (CoₓFe₁₀₀₋ₓ)_{100-y}B_{y} alloy (x being not less than 0 at. % and not more than 100 at. %, and y being not less than 0 at. % and not more than 30 at. %). The fixed magnetic layer may include, for example, an Fe—Co alloy.

The fixed magnetic layer may include, for example, a Co₉₀Fe₁₀ alloy having a fcc structure, Co having a hcp structure, or a Co alloy having a hcp structure. The fixed magnetic layer may include, for example, at least one selected from the group consisting of Co, Fe, and Ni. The fixed magnetic layer may include, for example, an alloy including the at least one material selected from these materials. The fixed magnetic layer may include, for example, an FeCo alloy material having a bcc structure, a Co alloy having a cobalt composition of 50% or more, or a material (a Ni alloy) having a Ni composition of 50% or more.

The fixed magnetic layer may include, for example, a Heusler magnetic alloy layer of Co₂MnGe, Co₂FeGe, Co₂MnSi, Co₂FeSi, Co₂MnAl, Co₂FeAl, Co₂MnGa_{0.5}Ge_{0.5}, Co₂FeGa_{0.5}Ge_{0.5}, etc. The fixed magnetic layer may include, for example, a Co₄₀Fe₄₀B₂₀ layer having a thickness of 3 nm.

The intermediate layers (e.g., the first intermediate layer 11M and the second intermediate layer 12M) include, for example, a metal, an insulator, or a semiconductor. The metal includes, for example, Cu, Au, Ag, etc. In the case where the Intermediate layer includes a metal, the thickness of the intermediate layer is, for example, not less than about 1 nm and not more than about 7 nm. The Insulator or semiconductor of the intermediate layer includes, for example, magnesium oxide (MgO, etc.), aluminum oxide (Al₂O₃, etc.), titanium oxide (TiO, etc.), zinc oxide (ZnO, etc.), gallium oxide (Ga—O), etc. In the case where the intermediate layer includes an insulator or a semiconductor, the thickness of the intermediate layer is, for example, not less than about 0.6 nm and not more than about 2.5 nm. The intermediate layer may include, for example, a CCP (Current-Confined-Path) spacer layer. For example, the CCP spacer layer has a structure in which a copper (Cu) metal path is formed inside an insulating layer of aluminum oxide (Al₂O₃). For example, the intermediate layer includes a MgO layer having a thickness of 1.6 nm.

### Fourth Embodiment

FIG. 12 is a schematic cross-sectional view illustrating a sensor according to a fourth embodiment.

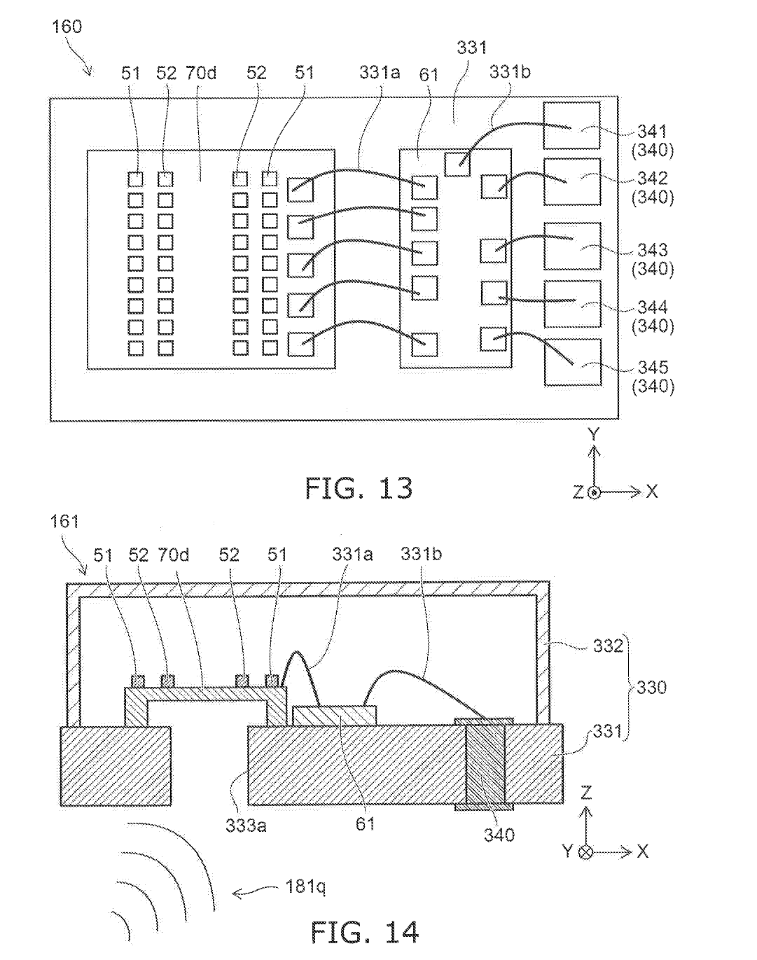

FIG. 13 is a schematic plan view illustrating the sensor according to the fourth embodiment.

These drawings illustrate components included in the sensor according to the embodiment.

As shown in FIG. 12 and FIG. 13, the sensor 160 further includes a housing 330 in addition to the film portion 70d, the first sensing elements 51, and the second sensing elements 52. The housing 330 is provided around the first sensing elements 51 and the second sensing elements 52. In the example, the processor 61 and multiple terminals 340 are provided inside the housing 330. The processor 61 is, for example, an ASIC (application specific integrated circuit).

In the example, the housing 330 includes a substrate 331 and a cover 332. The multiple terminals 340 are provided in the substrate 331. An acoustic hole 333 is provided in the cover 332. For example, the sound wave 181q passes through the acoustic hole 333 and enters the interior of the cover 332. For example, the film portion 70d is provided on the substrate 331. The processor 61 is electrically connected to the first sensing elements 51 and the second sensing elements 52 by interconnects 331a. A first terminal 341, a second terminal 342, a third terminal 343, a fourth terminal 344, and a fifth terminal 345 are provided as the multiple terminals 340. At least a portion of the multiple terminals 340 are electrically connected to the processor 61 by interconnects 331b.

For example, the first terminal 341 is used for the threshold setting. For example, the second terminal 342 is electrically connected to a power supply. For example, the third terminal 343 and the fourth terminal 344 are used respectively as output terminals (Output+/Output−). For example, the fifth terminal 345 is grounded.

For example, a space is provided between the film portion 70d, the first sensing elements 51, the second sensing elements 52, and the housing 330. For example, a space is formed between the film portion 70d, the first sensing elements 51, the second sensing elements 52, and the substrate 331. For example, a space is formed between the film portion 70d, the first sensing elements 51, the second sensing elements 52, and the cover 332. For example, the film portion 70d, etc., are protected. The film portion 70d can deform stably. The film portion 70d, the first sensing elements 51, and the second sensing elements 52 are provided between the substrate 331 and the cover 332.

### Fifth Embodiment

FIG. 14 is a schematic cross-sectional view illustrating a sensor according to a fifth embodiment.

As shown in FIG. 14, in the sensor 161 according to the embodiment as well, the housing 330 (e.g., the substrate 331 and the cover 332) is provided in addition to the film portion 70d, the first sensing elements 51, and the second sensing elements 52. In the example, an acoustic hole 333a is provided in the substrate 331.

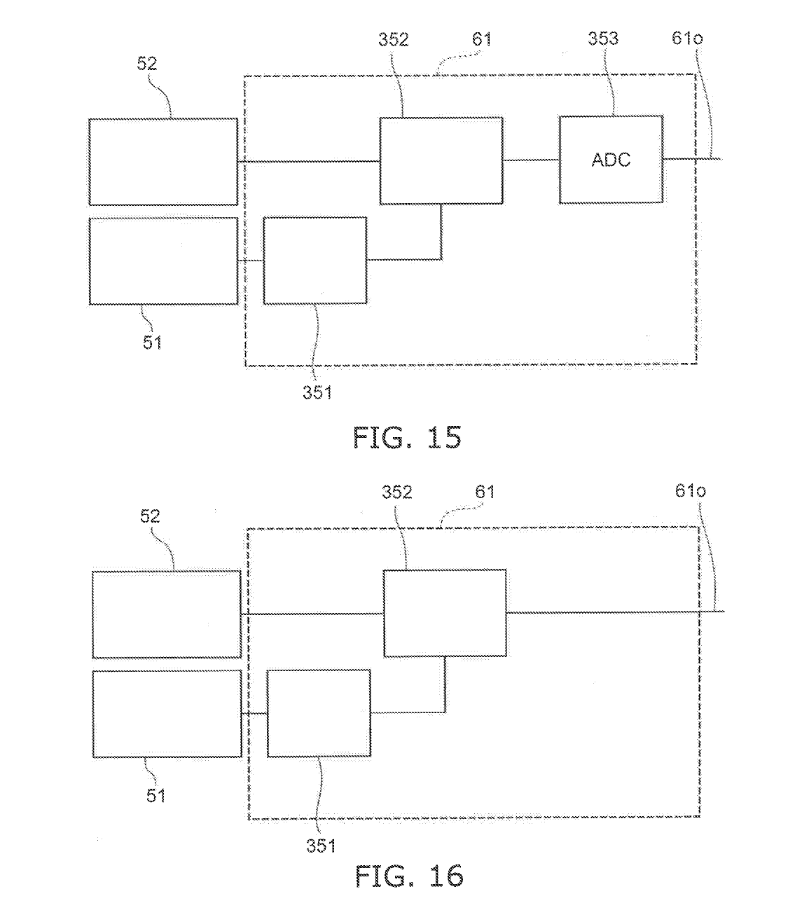

FIG. 15 is a schematic view illustrating the sensor according to the embodiment.

FIG. 15 shows an example of the processor 61. In the example, the processor 61 includes an amplifier circuit 351, an amplifying state-determination circuit 352, and an AD converter 353. The output of the first sensing element 51 is input to the amplifier circuit 351. The output of the amplifier circuit 351 is input to the amplifying state-determination circuit 352. The output of the second sensing element 52 is input to the amplifying state-determination circuit 352. The output of the amplifying state-determination circuit 352 is input to the AD converter 353. The output of the AD converter 353 is used as the output signal 610.

FIG. 16 is a schematic view illustrating the sensor according to the embodiment.

In FIG. 16, the processor 61 includes the amplifier circuit 351 and the amplifying state-determination circuit 352. For example, the sensor is used as an analog sensor.

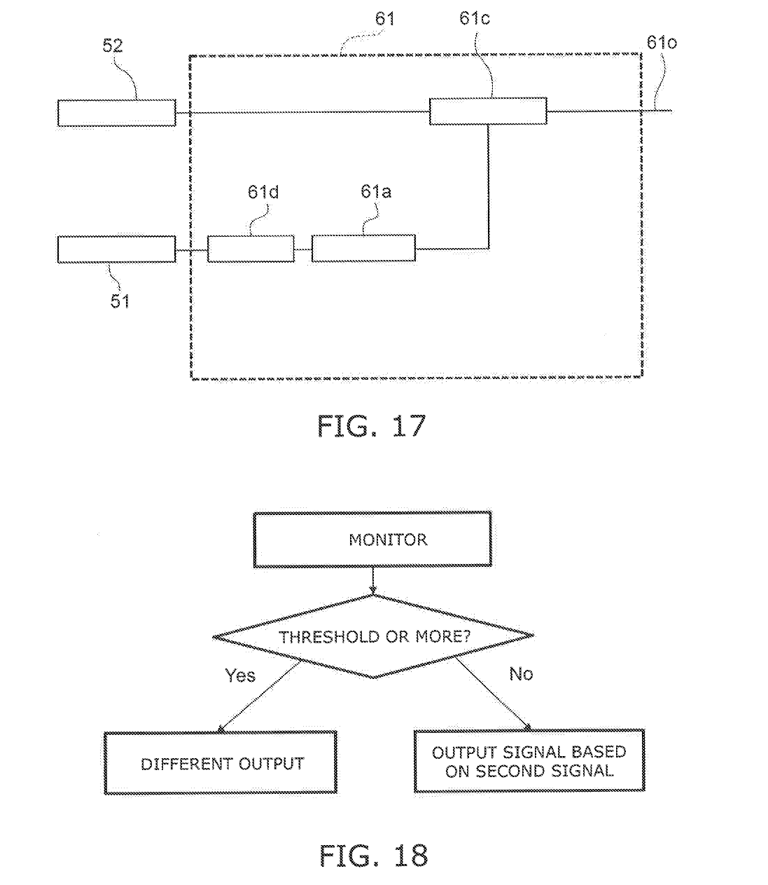

FIG. 17 is a schematic view illustrating the sensor according to the embodiment.

FIG. 17 shows an example of the processor 61. The processor 61 includes the full-wave rectifying circuit 61d, the comparison circuit 61a, and the output unit 61c. The output of the first sensing element 51 is input to the full-wave rectifying circuit 61d. The full-wave rectifying circuit 61d is, for example, an RMS/DC converter. The output of the full-wave rectifying circuit 61d is input to the comparison circuit 61a. The output of the comparison circuit 61a is input to the output unit 61c. The output of the second sensing element 52 is input to the output unit 61c. The amplification factor of the output unit 61c changes due to the output of the comparison circuit 61a. In the case where, for example, an operational amplifier (op-amp) or the like is used as the output unit 61c, for example, the resistance value of the resistance connected to the inverting input terminal of the op-amp changes due to the output of the comparison circuit 61a. Thereby, the amplification factor changes due to the output of the comparison circuit 61a.

The amplification factor of the output unit 61c is high in the case where the input to the comparison circuit 61a is lower than a threshold. In such a case, the second signal Sg2 (the high amplification factor) obtained from the second sensing element 52 is output from the output unit 61c as the output signal 61o. On the other hand, in the case where the input to the comparison circuit 61a is the threshold or more, the amplification factor of the output unit 61c is low. In such a case, the output of the output unit 61c is smaller than the output signal of the case where the input to the comparison circuit 61a is lower than the threshold. In other words, the output of the output unit 61c is different from the output signal recited above.

FIG. 18 is a schematic view illustrating the sensor according to the embodiment.

As shown in FIG. 18, for example, the operations of the comparison circuit 61a recited above may be performed by information processing. For example, the output of the first sensing element 51 is monitored; and the output is compared to the threshold. In the case where the output is lower than the threshold, the amplification factor of the second signal Sg2 obtained from the second sensing element 52 is set to be high.

In the case where the output is the threshold or more, the amplification factor of the second signal Sg2 obtained from the second sensing element 52 is set to be low.

The embodiment includes, for example, the following configurations (e.g., features).

### (Configuration 1)

A sensor, including:

a supporter;

a film portion supported by the supporter, the film portion deforming;

a first sensing element fixed to the supporter, the first sensing element including a first magnetic layer, a second magnetic layer, and a first intermediate layer, the first intermediate layer being provided between the first magnetic layer and the second magnetic layer;

a second sensing element fixed to the film portion, the second sensing element including a third magnetic layer, a fourth magnetic layer, and a second intermediate layer, the second intermediate layer being provided between the third magnetic layer and the fourth magnetic layer; and

a processor outputting an output signal based on a second signal when a first signal is in a first state, the first signal being obtained from the first sensing element, the second signal being obtained from the second sensing element,

an output of the processor being different from the output signal when the first signal is in a second state that is different from the first state.

### (Configuration 2)

A sensor, including:

a supporter;

a film portion supported by the supporter, the film portion deforming;

a first sensing element fixed to the supporter, the first sensing element including a first magnetic layer, a second magnetic layer, and a first intermediate layer, the first intermediate layer being provided between the first magnetic layer and the second magnetic layer;

a second sensing element fixed to the film portion, the second sensing element including a third magnetic layer, a fourth magnetic layer, and a second intermediate layer, the second intermediate layer being provided between the third magnetic layer and the fourth magnetic layer; and

a processor performing sensing based on a second signal when a first signal is in the first state, the first signal being obtained from the first sensing element, the second signal being obtained from the second sensing element.

### (Configuration 3)

A sensor, including:

a supporter;

a film portion supported by the supporter, the film portion deforming;

a first sensing element fixed to the supporter, the first sensing element including a first magnetic layer, a second magnetic layer, and a first intermediate layer, the first intermediate layer being provided between the first magnetic layer and the second magnetic layer;

a second sensing element fixed to the film portion, the second sensing element including a third magnetic layer, a fourth magnetic layer, and a second intermediate layer, the second intermediate layer being provided between the third magnetic layer and the fourth magnetic layer; and

a processor outputting an output signal based on a second signal when a first signal is in a first state, the first signal being obtained from the first sensing element, the second signal being obtained from the second sensing element.

### (Configuration 4)

The sensor according to one of Configurations 1 to 3, wherein an amplitude of the first signal in the first state is less than an amplitude of the first signal in the second state.

### (Configuration 5)

The sensor according to one of Configurations 1 to 4, wherein

an amplitude of the first signal in the first state is less than a threshold, and

an amplitude of the first signal in the second state is the threshold or more.

### (Configuration 6)

The sensor according to one of Configurations 1 to 5, wherein

the processor includes a comparison circuit and a switch circuit,

the comparison circuit compares the first signal to a reference value, and

based on an output of the comparison, the switch circuit allows or interrupts a current supplied to the second sensing element.

### (Configuration 7)

The sensor according to one of Configurations 1 to 5, wherein

the processor includes a comparison circuit, a switch circuit, and an output unit,

the comparison circuit compares the first signal to a reference value, and

based on an output of the comparison, the switch circuit allows or interrupts a path between the second sensing element and the output unit.

### (Configuration 8)

The sensor according to one of Configurations 1 to 7, wherein

the first signal includes a component of a first frequency, and

the second signal includes a component of a second frequency higher than the first frequency.

### (Configuration 9)

The sensor according to Configuration 8, wherein the second signal further Includes a component of the first frequency.

### (Configuration 10)

The sensor according to Configuration 8 or 9, wherein the second frequency is not less than 20 times and not more than 2000 times the first frequency.

### (Configuration 11)

The sensor according to one of Configurations 8 to 10, wherein

the first frequency is not less than 100 Hz and not more than 800 Hz, and

the second frequency is not less than 20 kHz and not more than 200 KHz.

### (Configuration 12)

The sensor according to one of Configurations 1 to 11, wherein

the first signal corresponds to a first resistance, the first resistance being between the first magnetic layer and the second magnetic layer, and the second signal corresponds to a second resistance, the

second resistance being between the third magnetic layer and the fourth magnetic layer.

### (Configuration 13)

The sensor according to one of Configurations 1 to 12, wherein

the first signal includes a first component corresponding to a change of a magnetic field received by the first sensing element, and

the second signal includes a second component corresponding to a deformation of the film portion.

### (Configuration 14)

The sensor according to Configuration 13, wherein the second signal further includes the first component.

### (Configuration 15)

The sensor according to Configuration 13 or 14, wherein

an angle between a magnetization of the first magnetic layer and a magnetization of the second magnetic layer changes according to the change of the magnetic field, and

an angle between a magnetization of the third magnetic layer and a magnetization of the fourth magnetic layer changes according to the deformation.

### (Configuration 16)

The sensor according to one of Configurations 1 to 15, further including:

a substrate; and

a cover,

the film portion, the first sensing element, and the second sensing element being provided between the substrate and the cover.

### (Configuration 17)

The sensor according to one of Configurations 1 to 15, further including a housing provided around the film portion, the first sensing element, and the second sensing element.

### (Configuration 18)

A sensor system, including:

the sensor according to one of Configurations 1 to 17; and

a communicator transmitting the output of the sensor.

### (Configuration 19)

An electric motor device, including:

the sensor according to one of Configurations 1 to 17; and

an electric motor,

the electric motor including a magnet and a member,

the member performing one motion of a displacement or a rotation based on a displacement of the magnet,

a sound wave and a magnetic field generated from the electric motor being applied to the sensor.

According to the embodiments, a sensor, a sensor system, and an electric motor device in which the sensitivity can be increased are provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in sensors such as holders (supporters), film portions, sensing elements, magnetic layers, intermediate layers, electrodes, processors, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all sensors, sensor systems, and electric motor devices practicable by an appropriate design modification by one skilled in the art based on the sensors, the sensor systems, and the electric motor devices described above as embodiments of the invention also are within the scope of the invention to the extent that the spirit of the Invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A sensor, comprising:
a supporter;
a film portion supported by the supporter, the film portion being deformable;
a first sensing element fixed to the supporter, the first sensing element including a first magnetic layer, a second magnetic layer, and a first intermediate layer, the first intermediate layer being provided between the first magnetic layer and the second magnetic layer;
a second sensing element fixed to the film portion, the second sensing element including a third magnetic layer, a fourth magnetic layer, and a second intermediate layer, the second intermediate layer being provided between the third magnetic layer and the fourth magnetic layer; and
a processor configured to output an output signal when a first signal is in a first state, the first signal being obtained from the first sensing element, the output signal being based on a second signal obtained from the second sensing element,
an output of the processor being different from the output signal when the first signal is in a second state different from the first state.

2. A sensor, comprising:
a supporter;
a film portion supported by the supporter, the film portion being deformable;
a first sensing element fixed to the supporter, the first sensing element including a first magnetic layer, a second magnetic layer, and a first intermediate layer, the first intermediate layer being provided between the first magnetic layer and the second magnetic layer;
a second sensing element fixed to the film portion, the second sensing element including a third magnetic layer, a fourth magnetic layer, and a second intermediate layer, the second intermediate layer being provided between the third magnetic layer and the fourth magnetic layer; and
a processor configured to perform sensing based on a second signal when a first signal is in the first state, the first signal being obtained from the first sensing element, the second signal being obtained from the second sensing element.

3. A sensor, comprising:
a supporter;
a film portion supported by the supporter, the film portion being deformable;
a first sensing element fixed to the supporter, the first sensing element including a first magnetic layer, a second magnetic layer, and a first intermediate layer, the first intermediate layer being provided between the first magnetic layer and the second magnetic layer;
a second sensing element fixed to the film portion, the second sensing element including a third magnetic layer, a fourth magnetic layer, and a second intermediate layer, the second intermediate layer being provided between the third magnetic layer and the fourth magnetic layer; and
a processor configured to output an output signal based on a second signal when a first signal is in a first state, the first signal being obtained from the first sensing element, the second signal being obtained from the second sensing element.

4. The sensor according to claim 1, wherein an amplitude of the first signal in the first state is less than an amplitude of the first signal in the second state.

5. The sensor according to claim 1, wherein
an amplitude of the first signal in the first state is less than a threshold, and
an amplitude of the first signal in the second state is the threshold or more.

6. The sensor according to claim 1, wherein
the processor Includes a comparison circuit and a switch circuit,
the comparison circuit compares the first signal to a reference value, and
based on an output of the comparison, the switch circuit allows or interrupts a current supplied to the second sensing element.

7. The sensor according to claim 1, wherein
the processor includes a comparison circuit, a switch circuit, and an output unit,
the comparison circuit compares the first signal to a reference value, and
based on an output of the comparison, the switch circuit allows or Interrupts a path between the second sensing element and the output unit.

8. The sensor according to claim 1, wherein
the first signal includes a component of a first frequency, and
the second signal includes a component of a second frequency higher than the first frequency.

9. The sensor according to claim 8, wherein the second signal further includes a component of the first frequency.

10. The sensor according to claim 8, wherein the second frequency is not less than 20 times and not more than 2000 times the first frequency.

11. The sensor according to claim 8, wherein
the first frequency is not less than 100 Hz and not more than 800 Hz, and
the second frequency is not less than 20 kHz and not more than 200 KHz.

12. The sensor according to claim 1, wherein
the first signal corresponds to a first resistance, the first resistance being between the first magnetic layer and the second magnetic layer, and
the second signal corresponds to a second resistance, the second resistance being between the third magnetic layer and the fourth magnetic layer.

13. The sensor according to claim 1, wherein
the first signal includes a first component corresponding to a change of a magnetic field received by the first sensing element, and
the second signal includes a second component corresponding to a deformation of the film portion.

14. The sensor according to claim 13, wherein the second signal further includes the first component.

15. The sensor according to claim 13, wherein
the first component includes a component of a change of a first resistance between the first magnetic layer and the second magnetic layer,
the second component includes a component of a change of a second resistance between the third magnetic layer and the fourth magnetic layer,
the first resistance changes according to the change of the magnetic field, and
the second resistance changes according to the deformation.

16. The sensor according to claim 1, further comprising:
a substrate; and
a cover,
the film portion, the first sensing element, and the second sensing element being provided between the substrate and the cover.

17. The sensor according to claim 1, further comprising a housing provided around the film portion, the first sensing element, and the second sensing element.

18. A sensor system, comprising:
the sensor according to claim 1; and
a communicator transmitting the output of the sensor.

19. An electric motor device, including:
the sensor according to claim 1; and
an electric motor,
the electric motor including a magnet and a member,
the member performing one motion of a displacement or a rotation based on a displacement of the magnet,
a sound wave and a magnetic field generated from the electric motor being applied to the sensor.
